(19) United States
(12) Patent Application Publication
(10) Pub. No.: US 2014/0186593 A1
(43) Pub. Date: Jul. 3, 2014

(54) RESIN COMPOSITION FOR PRINTED CIRCUIT BOARD, INSULATING FILM, PREPREG, AND PRINTED CIRCUIT BOARD

(71) Applicant: SAMSUNG ELECTRO-MECHANICS CO., LTD., Suwon-si (KR)

(72) Inventors: Young Kwan Seo, Suwon-si (KR); Jin Won Lee, Suwon-si (KR); Sung Nam Cho, Suwon-si (KR); Jun Young Kim, Suwon-si (KR); Hyun Jung Lee, Suwon-si (KR)

(73) Assignee: SAMSUNG ELECTRO-MECHANICS CO., LTD., Suwon-si (KR)

(21) Appl. No.: 14/140,426

(22) Filed: Dec. 24, 2013

(30) Foreign Application Priority Data
Dec. 28, 2012 (KR) 10-2012-0156601

(51) Int. Cl. H05K 1/03

(52) U.S. Cl. CPC H05K 1/0353; H05K 1/0373
USPC 428/195.1; 525/526; 523/429

(57) ABSTRACT

Disclosed herein are a resin composition for a printed circuit board, an insulating film, a prepreg, and a printed circuit board, the resin composition including: a composite epoxy resin containing a bisphenol A type epoxy resin, a cresol novolac epoxy resin, a rubber-modified epoxy resin, a phosphorus based epoxy resin, and an alkyl sulfonated tetrazole-modified epoxy resin; and a curing agent. The insulating film and the prepreg according to the present invention may have basically low coefficient of thermal expansion, excellent heat resistance, a high glass transition temperature, and excellent adhesion force with the metal.

### CROSS REFERENCE TO RELATED APPLICATION

This application claims the benefit of Korean Patent Application No. 10-2012-0156601, filed on Dec. 28, 2012, entitled “Resin Composition for Printed Circuit Board, Insulating Film, Prepreg, and Printed Circuit Board”, which is hereby incorporated by reference in its entirety into this application.

### BACKGROUND OF THE INVENTION

1. Technical Field

The present invention relates to a resin composition for a printed circuit board, an insulating film, a prepreg, and a printed circuit board.

2. Description of the Related Art

Generally, as a method of increasing adhesion force or close adhesion force between a resin and a metal in electronic products such as a printed circuit board, there are a method of allowing a surface of the resin to be rough by a desmear method to increase close adhesion force and a method of injecting an attachment (or adhesion) enhancing additive into the resin. In the present specification, the terms “attachment force”, “close adhesion force”, “adhesion force”, or the like, are equally or similarly used as meanings indicating a coupling force with a metal.

Meanwhile, in the case in which the surface of the resin is formed to be rough, as a line width of a wiring becomes thin, the roughness also becomes low, such that an effect of increasing the adhesion force or close adhesion force may be gradually weakened. Therefore, a role of the adhesion enhancing additive added in order to enhance the adhesion force becomes important. As the adhesive enhancing additive, a triazole based or tetrazole based material may enhance the adhesion force with the metal as disclosed in Patent Document 1.

In order to maximize an adhesion enhancing effect of the resin, the adhesion enhancing additive should be uniformly dispersed in the resin, and in order to uniformly disperse the additive, a method of dissolving the additive in a solvent or a method of injecting the additive in a powder form and then dispersing the additive has been suggested. However, in these methods, there are problems such as compatibility between the solvent for dissolving the resin and the resin and dispersion stability of the powder. In addition, an epoxy resin of which curing properties are improved by adding azoles such as triazole or tetrazole to an epoxy resin has been disclosed in Patent Document 2, but improvement of the adhesion force was not described therein.
Patent Document 1: European Patent Laid-Open Publication No. 0,665,468
Patent Document 2: U.S. Pat. Registration No. 4,322,459

### SUMMARY OF THE INVENTION

The present inventors discovered that the compound obtained by alkyl sulfonating tetrazole to be bonded with epoxy may achieve significantly excellent adhesion force with a metal, and the present invention was completed based on this discovery.

The present invention has been made in an effort to provide a resin composition for a printed circuit board including a composite epoxy resin containing an alkyl sulfonated tetrazole-modified epoxy resin having excellent adhesion force with a metal.

Further, the present invention has been made in an effort to provide an insulating film made of the resin composition to thereby have excellent adhesion force with a metal while maintaining heat resistance and mechanical properties.

Further, the present invention has been made in an effort to provide a prepreg formed by impregnating the resin composition to thereby have excellent adhesion force with the metal while maintaining heat resistance and mechanical properties.

Further, the present invention has been made in an effort to provide a printed circuit board including the insulating film or the prepreg.

According to a preferred embodiment of the present invention, there is provided a resin composition for a printed circuit board (first invention), the resin composition including: a composite epoxy resin containing a bisphenol A type epoxy resin, a cresol novolac epoxy resin, a rubber-modified epoxy resin, a phosphorus based epoxy resin, and an alkyl sulfonated tetrazole-modified epoxy resin represented by the following Chemical Formula 1; and a curing agent.

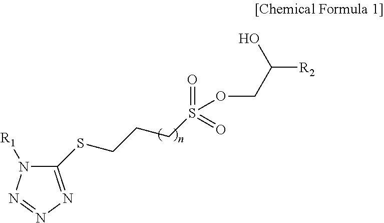

wherein,

R₁ is selected from aliphatic or alicyclic alkyl groups having 1 to 20 carbon atoms, aryl or aralkyl groups having 1 to 20 carbon atoms, functional group substituted alkyl or aryl groups having 1 to 20 carbon atoms, rings connected by alkylene with or without hetero atom, or a polymer compound, and derivatives thereof,

R₂ is a compound having at least one epoxy group per molecule, and n is an integer of 1 to 6.

R₂ may be at least one selected from a group consisting of bisphenol A, bisphenol F, bisphenol AD, catechol, polyphenols, polyglycidyl ether, glycidyl ether ester, polyglycidyl ester, epoxidized phenol novolac resin, epoxidized cresol novolac resins, epoxidized polyolefin, aliphatic epoxy resins, and urethane-modified epoxy resin.

The alkyl sulfonated tetrazole-modified epoxy resin may contain 1 to 50% of unreacted epoxy moieties.

The composite epoxy resin may be configured of 1 to 20 weight % of bisphenol A type epoxy resin, 30 to 60 weight % of cresol novolac epoxy resin, 1 to 20 weight % of rubber modified epoxy resin, 1 to 30 weight % of phosphorus based epoxy resin, and 1 to 20 weight % of alkyl sulfonated tetrazole-modified epoxy resin.

The curing agent may be at least one selected from an amide based curing agent, a polyamine based curing agent, an acid anhydride curing agent, a phenol novolac based curing agent, a polymercaptan based curing agent, a tertiary amine based curing agent, and an imidazole based curing agent.

The resin composition may further include at least one curing accelerator selected from a metal based curing accelerator, an imidazole based curing accelerator, and an amine based curing accelerator.

The resin composition may further include at least one inorganic filler selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

The resin composition may further include at least one thermoplastic resin selected from a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

According to another preferred embodiment of the present invention, there is provided an insulating film (second invention) made of the resin composition according to the first invention.

According to another preferred embodiment of the present invention, there is provided a prepreg manufactured by impregnating the resin composition according to the first invention into a substrate.

According to another preferred embodiment of the present invention, there is provided a printed circuit board including the insulating film according to the second invention.

According to another preferred embodiment of the present invention, there is to provided a printed circuit board comprising the prepreg according to the third invention.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a general printed circuit board capable of using a resin composition according to the preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

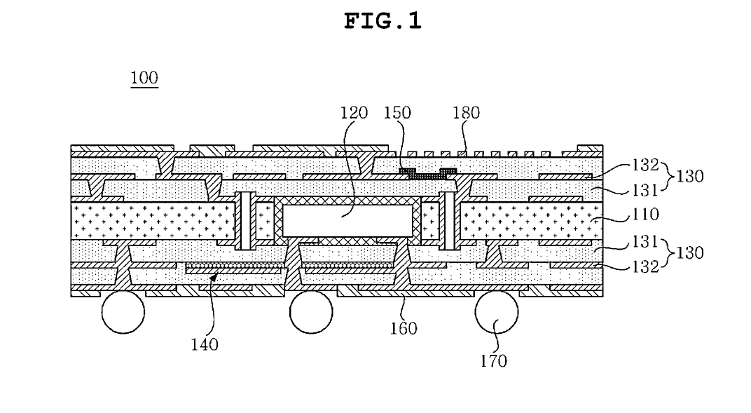

FIG. 1 is a cross-sectional view of a general printed circuit board capable of using a resin composition according to a first preferred embodiment of the present invention. Referring to FIG. 1, a printed circuit board 100 may be an embedded board on which electronic components are embedded. More specifically, the printed circuit board 100 may include an insulator or a prepreg 110 provided with a cavity, an electronic component 120 to disposed in the cavity, and a buildup layer 130 disposed on at least one of upper and lower surfaces of the insulator or the prepreg 110 including the electronic component 120. The buildup layer 130 may include an insulating layer 131 disposed on at least one of upper and lower surfaces of the insulator 110 and a circuit layer 132 disposed on the insulating layer 131 and connecting between layers.

Here, the electronic component 120 may be, for example, an active device such as a semiconductor device. In addition, the printed circuit board 100 may not include only one electronic component 120 embedded thereon but further include at least one additional electronic component, for example, a capacitor 140, a resistance device 150, and the like. In the preferred embodiment of the present invention, a kind or the number of electronic component is not limited thereto. Here, the insulator or the prepreg 110 and the insulating layer 131 may serve to insulate the circuit layers from each other or to insulate the electronic components from each other and simultaneously serve as a structural material for maintaining rigidity of a package.

In this case, when a wiring density of the printed circuit board 100 is increased, the insulator or the prepreg 110 and the insulating layer 131 need to have a low permittivity property in order to simultaneously decrease noise between the circuit layers and parasitic capacitance, and have a low dielectric loss property in order to improve an insulation property. As described above, at least one of the insulator or the prepreg 110 and the insulating layer 131 needs to have rigidity while reducing permittivity and dielectric loss.

In the present invention, in order to increase adhesion force with a metal while maintaining a basic property so that thermal expansion rates of the insulating layer and the prepreg are decreased and a high glass transition temperature is obtained, a resin composition forming the insulating layer and the prepreg contains a composite epoxy resin containing a bisphenol A type epoxy resin, a cresol novolac epoxy resin, a rubber-modified epoxy resin, a phosphorus based epoxy resin, and an alkyl sulfonated tetrazole-modified epoxy resin; and a curing agent.

According to the present invention, the alkyl sulfonated tetrazole-modified epoxy resin may be represented by the following Chemical Formula 1.

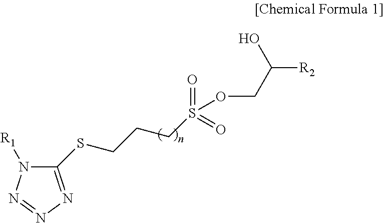

In Chemical Formula 1,

R₁ is selected from aliphatic or alicyclic alkyl groups having 1 to 20 carbon atoms, aryl or aralkyl groups having 1 to 20 carbon atoms, functional group substituted alkyl or aryl groups having 1 to 20 carbon atoms, rings connected by alkylene with or without hetero atom, or a polymer compound, and derivatives thereof,

R₂ is a compound having at least one epoxy group per molecule, and

n is an integer of 1 to 6.

The epoxy resin containing the alkyl sulfonated tetrazole compound represented by Chemical Formula 1 may be prepared by reacting an alkyl sulfonated tetrazole compound represented by the following Chemical Formula 2 with an epoxy compound represented by the following Chemical Formula 3.

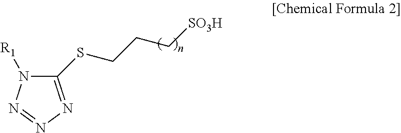

In Chemical Formula 2,

R₁ is selected from aliphatic or alicyclic alkyl groups having 1 to 20 carbon atoms, to aryl or aralkyl groups having 1 to 20 carbon atoms, functional group substituted alkyl or aryl groups having 1 to 20 carbon atoms, rings connected by alkylene with or without hetero atom, or a polymer compound and derivatives thereof. Preferably, R₁ may be aliphatic or alicyclic alkyl groups having 1 to 10 carbon atoms, aryl or aralkyl groups having 1 to 10 carbon atoms, functional group substituted alkyl or aryl groups having 1 to 10 carbon atoms, rings connected by alkylene with or without hetero atom, or a polymer compound, and derivatives thereof.

n is an integer of 1 to 6, and preferably, is 3 or 4.

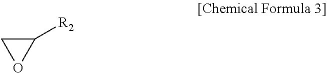

In Chemical Formula 3,

R₂ has the same definition as described above.

The reaction process is represented by the following Reaction Formula 1. The reaction was carried out in the presence of a solvent, and a reaction molar ratio of the alkyl sulfonated tetrazole compound to the epoxy compound may be stoichiometrically 1:0.5 to 1.5.

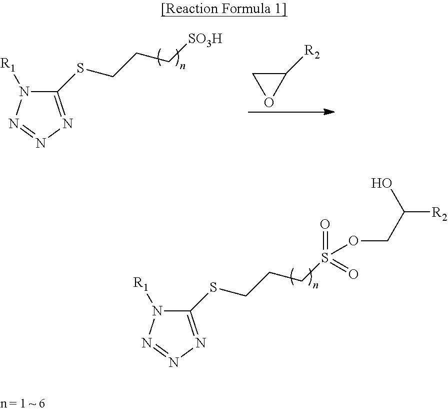

As shown in Reaction Formula 1, a resin having enhanced adhesion force with a metal was prepared by reacting some or all of the functional groups of the epoxy compound with the alkyl sulfonated tetrazole of Chemical Formula 2 to thereby introduce a tetrazole group, which is a functional group capable of enhancing adhesion force, into the resin.

As R₂ used in the present invention, any compound may be used as long as the compound has at least one epoxy group per molecule. For example, bisphenol A; bisphenol F; bisphenol AD; catechol; polyphenols such as resorcinol, or the like; polyglycidyl ether obtained by reacting polyalcohols such as glycerin, polyethylene glycol, or the like, with epichlorohydrin; glycidyl ether ester obtained by reacting hydroxycarboxylic acid such as p-hydroxybenzoic acid or β-hydroxynaphthoic acid with epichlorohydrin; polyglycidyl ester obtained by reacting polycarboxylic acid such as phthalic acid or terephthalic acid with epichlorohydrin; epoxidized phenol novolac resin; epoxidized cresol novolac resins; epoxidized polyolefin; aliphatic epoxy resins; other urethane-modified epoxy resins; mixture resins thereof, or the like, may be used. More preferably, bisphenol A, bisphenol F, epoxidized phenol novolac resins, and/or epoxidized cresol novolac resins, or the like, may be used.

Examples of the epoxy resin containing the alkyl sulfonated tetrazole compound according to the present invention includes a 3-(1-methyl-1H-tetrazole-5-ylthio)propane-1-sulfonyl cresol novolac resin, a 3-(1-methyl-1H-tetrazole-5-ylthio)butane-1-sulfonyl cresol novolac resin, a 3-(1-ethyl-1H-tetrazole-5-ylthio)propane-1-sulfonyl cresol novolac resin, a 3-(1-ethyl-1H-tetrazole-5-ylthio)butane-1-sulfonyl cresol novolac resin, and the like. The 3-(1-methyl-1H-tetrazole-5-ylthio)propane-1-sulfonyl cresol novolac resin represented by the following Chemical Formula 4 may be more preferable.

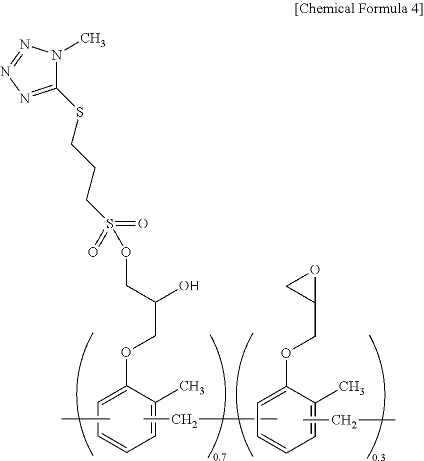

In the epoxy resin containing the alkyl sulfonated tetrazole compound according to the present invention, unreacted epoxy moieties may be completely substituted by adjusting a reaction equivalent. However, in order to maintain the adhesion force due to a curing reaction with other epoxy compounds and tetrazole, it may be effective that the unreacted epoxy moieties remain at a content of 1 to 50%.

In addition, the present invention provides a composite epoxy resin composition containing the epoxy resin containing the alkyl sulfonated tetrazole compound represented by Chemical Formula 1. The composite epoxy resin composition contains a bisphenol A type epoxy resin, a cresol novolac epoxy resin, a rubber-modified epoxy resin, a phosphorus based epoxy resin, and an alkyl sulfonated tetrazole-modified epoxy resin represented by Chemical Formula 1.

Preferably, the composite epoxy resin may be configured of 1 to 20 weight % of bisphenol A type epoxy resin, 30 to 60 weight % of cresol novolac epoxy resin, 1 to 20 weight % of rubber modified epoxy resin, 1 to 30 weight % of phosphorus based epoxy resin, to and 1 to 20 weight % of alkyl sulfonated tetrazole-modified epoxy resin.

The bisphenol A type epoxy resin is added at a content of 1 to 20 weight % in order to improve chemical resistance, adhesion, electrical insulation, and permittivity of a film. In the case in which the content is less than 1 weight %, physical and mechanical properties may be deteriorated, and in the case in which the content is more than 20 weight %, cracks may be generated due to brittleness. The cresol novolac epoxy resin is added at a content of 30 to 60 weight % in order to improve heat resistance and mechanical properties of the film. In the case in which the content is less than 30 weight %, it may be difficult to obtain an effect caused by the addition, and in the case in which the content is more than 60 weight %, electrical and mechanical properties may be deteriorated. The rubber-modified epoxy resin is added at a content of 1 to 20 weight % in order to improve adhesion force and toughness of a cured product. In the case in which the content is less than 1 weight %, the adhesion force and the toughness of the cured product may be decreased, and in the case in which the content is more than 20 weight %, electric insulation may be decreased, and elasticity may be increased, which may decrease dimensional stability. The phosphorus based epoxy resin is added at a content of 1 to 30 weight % in order to improve flame resistance of the cured product. In the case in which the content is less than 1 weight %, a problem in flame resistance may not be solved, and in the case in which the content is more than 30 weight %, the physical and mechanical properties of the cured product may be deteriorated. The alkyl sulfonated tetrazole-modified epoxy resin is added at a content of 1 to 20 weight % in order to enhance adhesion force with a metal. In the case in which the content is less than 1 weight %, the adhesion force with the metal may be weak, and in the case in which the content is more than 20 weight %, moisture resistance may be deteriorated.

The resin composition according to the present invention may contain the curing agent for process efficiency. The curing agent is preferably at least one selected from an amide based curing agent, a polyamine based curing agent, an acid anhydride curing agent, a phenol novolac based curing agent, a polymercaptan based curing agent, a tertiary amine based curing agent, and an imidazole based curing agent, but is not particularly limited thereto.

The content of the used curing agent is preferably 0.1 to 3 weight %. In the case in which the content is less than 0.1 weight %, curing at a high temperature may be difficult, or a curing rate may be decreased, and in the case in which the content is more than 3 weight %, since the curing rate is excessively rapid, it may be difficult to apply the curing agent during a process or storage stability is decreased, and unreacted curing agent may remain after the reaction, such that a moisture absorption rate of an insulating film or the prepreg may increase, thereby deteriorating the electrical properties.

The resin composition according to the present invention further contains an inorganic filler in order to decrease coefficient of thermal expansion (CTE) of the epoxy resin. The inorganic filler is used to decrease the coefficient of thermal expansion, and a content of the inorganic filler based on the resin composition may be different according to the required characteristics in consideration of a use of the resin composition, or the like, but may be preferable 40 to 80 weight %. When the content is less than 40 weight %, the dielectric loss tangent may be decreased and the thermal expansion rate may be increased, and when the content is more than 80 weight %, adhesion strength may be decreased.

As a specific example of the inorganic filler used in the present invention, there are silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, calcium zirconate, and the like. Among them, one kind or a combination of at least two kinds may be used. Particularly, the silica having a low dielectric loss tangent may be preferable.

In addition, when an average particle size of the inorganic filler is more than 5 μm, it may be difficult to stably form a fine pattern at the time of forming a circuit pattern on a conductive layer. Therefore, the average particle size may be preferably 5 μm or less. to Further, the inorganic filler may be surface-treated with a surface treating agent such as a silane coupling agent, or the like, in order to improve the moisture resistance. The silica having a diameter of 0.05 to 5 μm may be more preferable.

The resin composition according to the present invention may selectively contain a curing accelerator to effectively perform the curing. As the curing accelerator used in the present invention, there are a metal based curing accelerator, an imidazole based curing accelerator, an amine based curing accelerator, and the like. Among them, one kind or a combination of at least two kinds may be added as a general content amount used in the art.

The metal based curing accelerator is not particularly limited but may be, for example, an organic metal complex or an organic metal salt of a metal such as cobalt, copper, zinc, iron, nickel, manganese, tin, or the like. Specific examples of the organic metal complex may include an organic cobalt complex such as cobalt (II) acetylacetonate, cobalt (III) acetylacetonate, or the like, an organic copper complex such as copper (II) acetylacetonate, or the like, an organic zinc complex such as zinc (II) acetylacetonate, or the like, an organic iron complex such as Fe (III) acetylacetonate, or the like, an organic nickel complex such as nickel (II) acetylacetonate, or the like, an organic manganese complex such as manganese (II) acetylacetonate, or the like. Specific examples of the organic metal salt may include zinc octylate, tin octylate, zinc naphthenate, cobalt naphthenate, tin stearate, zinc stearate, or the like. As the metal base curing accelerator, cobalt (II) acetylacetonate, cobalt (III) acetylacetonate, zinc (II) acetylacetonate, zinc naphthenate, Fe (III) acetylacetonate may be preferable in view of curability and solubility in solvent. Particularly, cobalt (II) acetylacetonate and zinc naphthenate may be preferable. One kind of metal based curing accelerator or a combination of at least two kinds thereof may be used.

The imidazole based curing accelerator is not particularly limited but may be an imidazole compound such as 2-methyl imidazole, 2-undecyl imidazole, 2-heptadecyl imidazole, 1,2-dimethyl imidazole, 2-ethyl-4-methyl imidazole, 2-phenyl imidazole, 2-phenyl-4-methyl imidazole, 1-benzyl-2-methyl imidazole, 1-benzyl-2-phenyl imidazole, 1-cyanoethyl-2-methyl imidazole, 1-cyanoethyl-2-undecyl imidazole, 1-cyanoethyl-2-ethyl-4-methyl imidazole, 1-cyanoethyl-2-phenyl imidazole, 1-cyanoethyl-2-undecyl imidazolium trimellitate, 1-cyanoethyl-2-phenyl imidazolium trimellitate, 2,4-diamino-6-[2′-methyl-imidazolyl-(1′)]-ethyl-s-triazine, 2,4-diamino-6-[2′-undecyl imidazolyl-(1′)]-ethyl-s-triazine, 2,4-diamino-6-[2′-ethyl-4′-methyl imidazolyl-(1′)]ethyl-s-triazine, 2,4-diamino-6-[Z-methyl imidazolyl-(1′)]ethyl-s-triazine isocyanulic acid adduct,2-phenyl imidazole isocyanulic acid adduct, 2-phenyl-4,5-dihydroxy methyl imidazole, 2-phenyl-4-methyl-5-hydroxy methyl imidazole, 2,3-dihydroxy-1H-pyroro[1,2-a]benzimidazole, 1-dodecyl-2-methyl-3-benzylimidazolium chloride, 2-methyl imidazoline, 2-phenyl imidazoline, or the like, and an adduct of the imidazole compound and the epoxy resin. One kind of imidazole based curing accelerator or a combination of at least two kinds thereof may be used.

The amine based curing agent is not particularly limited but may be trialkylamine such as triethylamine, tributylamine, or the like, and an amine compound such as 4-dimethylaminopyridine, benzyldimethylamine, 2,4,6-tris(dimethyaminomethyl)phenol, 1,8-diazabicyclo(5,4,0)-undecence (hereinafter, referred to as “DBU”), or the like. One kind of amine based curing accelerator or a combination of at least two kinds thereof may be used.

The resin composition according to the present invention may selectively contain a thermoplastic resin in order to improve a film property of the resin composition and mechanical property of cured products. An example of the thermoplastic resin may include a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, a polyester resin, or the like. One kind of thermoplastic resin or a mixture of at least two thereof may be used. The thermoplastic resin may have a weight average molecular weight of 5,000 to 200,000. In the case in which the weight average molecular weight is less than 5,000, an effect of improving film formability or mechanical strength may not be sufficiently exhibited, and in to the case in which the weight average molecular weight is more than 200,000, compatibility with the epoxy resin may not be sufficient, surface unevenness may be increased after curing, and it may be difficult to form a high density fine pattern. Specifically, the weight average molecular weight may be measured using LC-9A/RID-6A manufactured by Shimadzu Corporation as a measuring device, Shodex K-800P/K-804L/K-804L manufactured by Showa Denko K. K. as a column, and chloroform (CHCl₃), as a mobile phase, or the like, at a column temperature of 40° C., and calculated using a calibration curve of standard polystyrene.

In the case of adding the thermoplastic resin to the resin composition according to the present invention, a content of the thermoplastic resin in the resin composition is not particularly limited but may be preferably 0.1 to 10 weight %, more preferably, 1 to 5 weight % based on 100 weight % of non-volatile component in the resin composition. When the content of the thermoplastic resin is less than 0.1 weight %, the effect of improving film formability or mechanical strength may not be exhibited, and when the content is more than 10 weight %, melt viscosity may be increased, and surface roughness of the insulating layer after a wet roughening process may be increased.

The insulating resin composition according to the present invention may be mixed in the presence of an organic solvent. As the organic solvent, 2-methoxy ethanol, acetone, methyl ethyl ketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethyl formamide, and dimethyl acetamide may be used in consideration of solubility and miscibility of the resin and other additives used in the present invention, but the present invention is not limited thereto.

It may be preferable in view of manufacturing an insulating film that a viscosity of the resin composition according to the present invention is preferably 1000 to 2000 cps in the case in which the inorganic filler is not contained and is 700 to 1500 cps in the case in to which the inorganic filler is contained, and the resin composition may have a property of maintaining an appropriate viscosity at room temperature. The viscosity of the resin composition may be adjusted by changing a content of a solvent. The non-voltaic component except for the solvent may be 30 to 70 weight % of the resin composition. In the case in which the viscosity of the resin composition is out of the above-mentioned range, it may be difficult to form the insulating film, or although the insulating film is formed, it may be difficult to mold a member.

In addition, in the case of using copper foil (12 μm), peel strength of the insulating film may be 1.0 kN/m or more. The insulating film made of the resin composition according to the present invention may have the coefficient of thermal expansion (CTE) of 5 to 50 ppm/° C. when the inorganic filler is not contained. In addition, the glass transition temperature Tg may be more than 210° C., preferably 220 to 270° C.

In addition, the resin composition according to the present invention may further contain additives such as a softener, a leveling agent, a plasticizer, an antioxidant, a flame retardant, a flame retardant adjuvant, a lubricant, an antistatic agent, a colorant, a heat stabilizer, a light stabilizer, a UV absorbent, a coupling agent, and/or a precipitation preventing agent that are known by those skilled in the art, as needed.

The insulating resin composition according to the present invention may be manufactured as a dry film in a semi-solid state by any general method known in the art. For example, the insulating resin composition may be manufactured and dried in a film shape using a roller coater, a curtain coater, or the like, and then the dried resin composition may be applied onto a substrate to thereby be used as an insulating layer (or an insulating film) or a prepreg at the time of manufacturing a multi-layer printed circuit board by a build-up process. This insulating film or the prepreg may have a coefficient of thermal expansion (CTE) of 50 ppm/° C. or less.

The prepreg may be prepared by applying or impregnating the resin composition according to the present invention into a reinforcement material, curing and drying the to resultant, and then removing the solvent. Examples of an impregnation method include a dip coating method, a roll coating method, and the like. Examples of the reinforcement material may include glass cloth, alumina glass cloth, non-woven glass fabric, non-woven cellulose fabric, woven carbon cloth, polymer cloth, and the like. Further, the examples of the reinforcement material may further include glass fiber, silica glass fiber, carbon fiber, alumina fiber, silicon carbide fiber, asbestos, rock wool, mineral wool, gypsum whisker, and a woven or non-woven fabric thereof, aromatic polyamide fiber, polyimide fiber, liquid crystal polyester, polyester fiber, fluorinated fiber, polybenzoxazole fiber, glass fiber including polyamide fiber, glass fiber including carbon fiber, glass fiber including polyimide fiber, glass fiber including aromatic polyester, glass paper, mica paper, alumina paper, craft paper, cotton paper, paper-glass bond paper, and the like, a combination comprising at least one of the foregoing, and the like. At least one thereof may be mixed and used. In this case, the glass fiber may have a thickness of 5 to 200 μm. The resin composition may be impregnated at a content of 0.4 to 3 parts by weight based on 1 part of the reinforcement material. In the case in which the resin composition is impregnated in a range described above, when two or more prepregs are used, close adhesion force between the prepregs may be excellent, and mechanical strength and dimensional stability of the prepreg may be excellent. The curing may be performed at 150 to 350 C. As described above, heat treatment may be performed at a low temperature, thereby making it possible to manufacture a printed circuit board using the prepreg.

The prepreg may be bonded with copper. That is, the prepreg prepared by performing a heat treatment process in a semi-solid state after the resin composition according to the present invention is impregnated into the reinforcement material is positioned on copper foil, and then heat treatment may be performed thereon. When the solvent is removed and the heat treatment is performed, a member in which copper and the prepreg are bonded with each other may be prepared. In order to evaporate the solvent, the prepreg impregnated copper foil may be heated under reduced pressure or be ventilated. Examples of an application method may include a roller coating method, a dip coating method, a spray coating method, a spin coating method, a curtain coating method, a slit coating method, a screen printing method, and the like.

In addition, a film may be manufactured using a resin composition solution itself. More specifically, the film may be manufactured on a substrate by forming a solution layer of the resin composition on the substrate using a solvent casting method and removing a solvent from the solution layer. Examples of the substrate may include metal foil such as copper foil, aluminum foil, gold foil, silver foil, or the like, a glass substrate, a polyethylene terephthalate (PET) film, or the like.

According to another preferred embodiment of the present invention, there is provided a printed circuit board manufactured using the resin composition. The printed circuit board may be configured of a film, a printed board, a copper clad laminate, a prepreg, or a combination thereof. In addition, the printed circuit board may be a copper clad laminate (CCL) or a flexible copper clad laminate.

Further, the printed circuit board may include the prepreg described above. In this case, the printed circuit board may be manufactured by laminating a metal layer on the prepreg, putting and pressing the prepreg into a press, fusing the prepreg by heating, and curing the prepreg. As a material of the metal layer, copper, aluminum, iron, stainless steel, nickel, or the like, or an alloy thereof may be used. In addition, the printed circuit board may be a printed circuit board in which metal layers are laminated on both sides of the prepreg or a printed circuit board in which a plurality of prepreg layers are compressed. In addition, the printed circuit board including the prepreg may be variously changed and used. A conductive pattern may be formed on one surface or both surfaces of the printed circuit board and have a multilayer structure of four layers, eight layers, or the like.

Hereinafter, the present invention will be described with reference to the Examples, but the present invention is not limited thereto.

### Preparation Example 1

### Synthesis of 3-(1-methyl-1H-tetrazole-5-ylthio)propane-1-sulfonic acid

90 g of acetonitrile as a reaction solvent, 20 g of 5-mercapto-1-methyltetrazole (0.172 mol, and 21 g of 1,3-propanesultone (0.172 mol) were weighed, respectively, and put into a 250 ml one-neck flask installed with a reflux condenser, followed by reflux at about 80° C. under nitrogen atmosphere. After a reaction end point was determined by a thin layer chromatography (TLC, developing solvent: chloroform:methanol=10:1) analysis and the reaction was ended, the reactant material was filtered using Celite 545. Then, the filtrate was concentrated under reduced pressure and purified using a silica column chromatography, thereby obtaining 3-(1-methyl-1H-tetrazole-5-ylthio)propane-1-sulfonic acid. A synthesis yield was 68%, and a melting point (DSC: differential scanning calorimetry) was 98° C.

¹H-NMR (CDCl₃,δ) 3.63 (s, 3H,tetrazole-CH₃), 3.40 (t, 2H, —S—CH₂CH₂CH₂—SO₃—) 2.95 (t, 2H, —S—CH₂CH₂CH₃—SO₃—), 2.20 (m, 2H, —S—CH₂CH₂CH₃—SO₃—)

### Example 1

100 g of methylethylketone (MEK) as a reaction solvent, 23.8 g of 3-(1-methyl-1H-tetrazole-5-ylthio)propane-1-sulfonic acid (0.1 equivalent) obtained in Preparation Example 1, and 20.8 g of cresol novolac epoxy (YDCN500-80P, 0.1 equivalent) were weighed, respectively, and put into a 250 ml one-neck flask installed with a reflux condenser, followed by stirring at about 50° C. under nitrogen atmosphere After a reaction end point was determined by measuring and analyzing acid value, and the reaction was ended, the reactant material was precipitated in ethylether, thereby obtaining a tetrazole substituted epoxy derivative. The obtained derivative was represented by Chemical Formula 4. A synthesis yield (tetrazole substitution rate: 70%) was 85%, and a softening point was 73° C.

¹H-NMR (CDCl₃,δ) 3.66 (s, 3H,tetrazole-CH₃), 3.41 (t, 2H, —S—CH₂CH₂CH₂—SO₃—) 2.93 (t,2H, —S—CH₂CH₂CH₃—SO₃—), 2.25 (m, 2H, —S—CH₂CH₂CH₃—SO₃—), 3.58 (m, 2H, —SO₃—CH₂CHCH₂—), 3.86 (m, 1H, —SO₃—CH₂CHCH₂—), 4.12 (m, 2H, —SO₃—CH₂CHCH₂—).

### Example 2

### Manufacturing Insulation Film Containing Tetrazole Substituted Epoxy

80 g of bisphenol A type epoxy resin “YD-011” (epoxy equivalent 469, Kukdo Chemical Co.), 160 g of cresol novolac epoxy resin, 400 g of rubber-modified epoxy resin, 40 g of phosphorus based flame retardant epoxy resin, 80 g of 3-(1-methyl-1H-tetrazole-5-ylthio)propane-1-sulfonyl cresol novolac resin prepared in Example 1 (tetrazole substitution rate: 60%), and 65 weight % of spherical silica slurry (average particle size: 0.3 μm, solvent: MEK, 923 g) were mixed and dispersed using a bead mill 0.5 phr of 2-ethyle-4-methylimidazole was dissolved in the composition as described above as a curing agent to prepare resin varnish. The prepared resin varnish was applied onto a polyethylene terephthalate (PET) film having a thickness of 38 μm using a bar coater and dried for about 10 minutes so as to have a resin thickness of about 30 μm after drying.

### Comparative Example 1

80 g of bisphenol A type epoxy resin “YD-011” (epoxy equivalent 469, Kukdo Chemical Co.), 240 g of cresol novolac epoxy resin, 400 g of rubber-modified epoxy resin, 40 g of phosphorus based flame retardant epoxy resin, and 65 weight % of spherical silica slurry (average particle size: 0.3 μm, solvent: MEK, 923 g) were mixed and dispersed using a bead mill 0.5 phr of 2-ethyle-4-methylimidazole was dissolved in the composition as described above as a curing agent to prepare resin varnish. The prepared resin varnish was applied onto a polyethylene terephthalate (PET) film having a thickness of 38 μm using a bar coater and dried for about 10 minutes so as to have a resin thickness of about 30 μm after drying.

### Experimental Example

### Laminate of Insulating Resin Sheet

The insulating films obtained in Example 2 and in Comparative Example 1 was laminated on one surface of an inner layer circuit board (thickness: 0.8 mm, a conductor thickness: 18m) by performing vacuum suction at about 80° C. for 20 seconds and pressing the insulating film at about 80° C. and pressure of about 7.5 kg/cm² using a vacuum pressure to laminator manufactured by Meiki Co. LTD.

Curing of Resin Composition

The PET protective film was separated from the laminated insulating film, followed by curing at about 160° C. for about 30 minutes using a hot wind circulating furnace, such that a laminated plate in which the insulating layer is formed on one surface of the inner circuit board was obtained.

Roughening Treatment

The obtained laminated plate was roughened using a potassium permanganate solution to form surface roughness. The roughening treatment was performed as follows. The laminated plate was immersed in a swelling solution (Swelling Dip Securiganth P manufactured by Atotech Japan) at about 60° C. for about 10 minutes, and then immersed in an oxidation solution (a mixed solution of Concentrate. Compact CP and Dosing Solution. Securiganth P manufactured by Atotech Japan) at about 80° C. for about 20 minutes. Next, the laminated plate was immersed in a reduction solution (Reduction solution Securiganth P500 manufactured by Atotech Japan) at about 40° C. for about 5 minutes.

Formation of Conductive Layer by Plating

After forming a palladium (Pd) catalyst in the surface of the insulating layer, electroless plating was performed on a surface of the insulating layer of the roughened laminated plate using a printganth MSK-DK manufactured by Atotech, Japan. Then, electro plating was performed using copper sulfate so that a thickness of a copper layer becomes about 20 μm. A sample of which the electro plating was completed was finally cured at about 170° C. for about 50 minutes.

Evaluation of Adhesion Strength

After the conductive layer formed by electro plating was cut so as to have a width of 10 mm and a length of 100 mm, adhesion strength was evaluated at a rate of 50.8 mm/min and at a length of 30 mm using a Z050 universal testing machine (UTM) manufactured by to Zwick. The results were shown in Table 1.

TABLE 1

| Classification | Adhesion strength (kgf/cm) |
|---|---|
| Comparative Example 1 | 0.31 |
| Example 2 | 0.45 |

As shown in Table 1, the epoxy resin containing the alkyl sulfonated tetrazole compound according to the present invention had excellent adhesion strength, about 1.5 times higher than that of a general epoxy resin.

The resin composition for a printed circuit board according to the present invention, and the insulating film and the prepreg manufactured using the same may have basically low coefficient of thermal expansion, excellent heat resistance, a high glass transition temperature, and excellent adhesion force with the metal.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A resin composition for a printed circuit board, the resin composition comprising:
a composite epoxy resin containing a bisphenol A type epoxy resin, a cresol novolac epoxy resin, a rubber-modified epoxy resin, a phosphorus based epoxy resin, and an alkyl sulfonated tetrazole-modified epoxy resin represented by the following Chemical Formula 1; and
a curing agent. 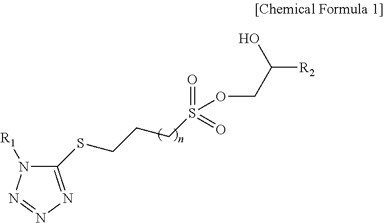
wherein,
R₁ is selected from aliphatic or alicyclic alkyl groups having 1 to 20 carbon atoms, aryl or aralkyl groups having 1 to 20 carbon atoms, functional group substituted alkyl or aryl groups having 1 to 20 carbon atoms, rings connected by alkylene with or without hetero atom, or a polymer compound, and derivatives thereof,
R₂ is a compound having at least one epoxy group per molecule, and n is an integer of 1 to 6.

2. The resin composition as set forth in claim 1, wherein R₂ is at least one selected from a group consisting of bisphenol A, bisphenol F, bisphenol AD, catechol, polyphenols, polyglycidyl ether, glycidyl ether ester, polyglycidyl ester, epoxidized phenol novolac resin, epoxidized cresol novolac resins, epoxidized polyolefin, aliphatic epoxy resins, and urethane-modified epoxy resin.

3. The resin composition as set forth in claim 1, wherein the alkyl sulfonated tetrazole-modified epoxy resin contains 1 to 50% of unreacted epoxy moieties.

4. The resin composition as set forth in claim 1, wherein the composite epoxy resin to is configured of 1 to 20 weight % of bisphenol A type epoxy resin, 30 to 60 weight % of cresol novolac epoxy resin, 1 to 20 weight % of rubber modified epoxy resin, 1 to 30 weight % of phosphorus based epoxy resin, and 1 to 20 weight % of alkyl sulfonated tetrazole-modified epoxy resin.

5. The resin composition as set forth in claim 1, wherein the curing agent is at least one selected from an amide based curing agent, a polyamine based curing agent, an acid anhydride curing agent, a phenol novolac based curing agent, a polymercaptan based curing agent, a tertiary amine based curing agent, and an imidazole based curing agent.

6. The resin composition as set forth in claim 5, further comprising at least one curing accelerator selected from a metal based curing accelerator, an imidazole based curing accelerator, and an amine based curing accelerator.

7. The resin composition as set forth in claim 1, further comprising at least one inorganic filler selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

8. The resin composition as set forth in claim 1, further comprising at least one thermoplastic resin selected from a phenoxy resin, a polyimide resin, a polyamideimide (PAI) resin, a polyetherimide (PEI) resin, a polysulfone (PS) resin, a polyethersulfone (PES) resin, a polyphenyleneether (PPE) resin, a polycarbonate (PC) resin, a polyetheretherketone (PEEK) resin, and a polyester resin.

9. An insulating film made of the resin composition as set forth in claim 1.

10. A prepreg manufactured by impregnating the resin composition as set forth in claim 1 into a substrate.

11. A printed circuit board comprising the insulating film as set forth in claim 9.

12. A printed circuit board comprising the prepreg as set forth in claim 10.
